(19) United States
(12) Patent Application Publication
(10) Pub. No.: US 2003/0020165 A1
(43) Pub. Date: Jan. 30, 2003

(54) Semiconductor device, and method for manufacturing the same

(75) Inventor: Kazuki Matsumoto, Chino-shi (JP)

Correspondence Address: OLIFF & BERRIDGE, PLC, P.O. BOX 19928, ALEXANDRIA, VA, 22320, US

(73) Assignee: Seiko Epson Corporation, Tokyo (JP)

(21) Appl. No.: 10/194,073

(22) Filed: Jul. 15, 2002

(30) Foreign Application Priority Data
Jul. 13, 2001 (JP) 2001-213423
May 9, 2002 (JP) 2002-134663

(51) Int. Cl. H01L 21/4763; H01L 23/48; H01L 29/40

(52) U.S. Cl. 257/751; 438/627; 257/774; 438/629; 438/637

(57) ABSTRACT

The invention provides a semiconductor device having a wiring structure that reduces the particle problem and achieves a low contact resistance and a high barrier property. The invention also provides a method for manufacturing the same. A diffusion layer relating to a circuit element is formed in a Si semiconductor substrate, and a barrier layer is provided between a conduction member and the diffusion layer. The barrier layer includes a Ti layer as a barrier metal. The Ti layer forms a silicide connection section on the side it contacts the diffusion layer. Furthermore, the barrier layer includes nitride and oxide layers of the Ti layer, more specifically, extremely thin TiN layer and TiOₓ layer, on the side it contacts the conduction member. The TiOₓ layer is an amorphous layer that is thinner than the TiN layer.

### BACKGROUND OF THE INVENTION

1. Field of the Invention

The present invention relates to a semiconductor device having a minute wring structure that requires a connecting section having a low resistance and with a high barrier property against Si. The invention also relates to a method for manufacturing such a semiconductor device.

2. Description of Related Art

Integrated circuit wirings in a semiconductor device are often formed of multiple layers with interlayer dielectric layers (SiO₂ films) interposed among the wirings. Each wiring itself is not a single layer, and instead is formed of multiple layers because functional layers, such as a barrier metal and an anti-reflection film, are added to the wiring.

A barrier metal is formed because of its barrier property against Si, its stability of electrical connection and the like when a wiring structure is formed of aluminum as a main composition. The barrier material also needs to be formed of a material that has a good cohesion property with an interlayer dielectric layer (SiO₂).

FIG. 10 is a cross-sectional view of a wiring structure of a contact section in a conventional semiconductor device. A wiring layer structure, which is connected to a diffusion layer 31 in a Si element surface that forms an integrated circuit, is generally formed with a contact hole 33 provided over an interlayer dielectric layer 32 formed of a Si0₂ film. A stacked layer containing a Ti layer 341/TiN layer 342 as a barrier metal is formed at a bottom section of the contact hole 33 (on the diffusion layer 31), and a layer substantially formed of aluminum 36 is formed thereon. The aluminum layer 36 has an Al-Cu structure that contains, for example, at least a minute amount (about 0.5%) of Cu.

The stacked layer of the barrier layer containing the Ti layer 341/TiN layer 342 is structured because of its coherency and barrier property with respect to Si (the diffusion layer 31). The Ti layer 341 and TiN layer 342 are continuously formed in the same sputter apparatus equipped with a Ti target (where the TiN layer 342 is sputter-formed in a nitrogen atmosphere).

The TiN layer 342 acts to control reactions between A1 in the aluminum layer 36 and Si in the device element. Also, the TiN layer 342 is effective in controlling reactions between the aluminum layer 36 and the Ti layer 341.

### SUMMARY OF THE INVENTION

The Ti layer 341/TiN layer 342 in the stacked barrier layer are successively formed by the continuous sputtering, which may eventually result in a problematic increase in the amount of particles. The increase in the amount of particles causes a lowered manufacturing yield.

Reactions between Al and Ti can be suppressed by the TiN layer 342 because of the structure described above. However, reactions of the Ti layer 341 with Si in the diffusion layer 31 eventually progress, and a thin TiO₂ layer 35 is formed on a surface of the Ti layer 341 that has been in contact with Si. The presence of the TiO₂ layer 35 possibly leads to a deterioration of the coherency and an increase in the resistance.

The present invention addresses the problems described above and provides a semiconductor device having a wiring structure that reduces the particle problem and achieves a low contact resistance and a high barrier property. The invention also provides a method for manufacturing such a semiconductor device.

A semiconductor device in accordance with the present invention includes a Si layer, a dielectric layer and a conductive member. The Si layer and the metal layer are connected to each other through Ti, TiN and an oxide film provided in a contact hole defined in the dielectric layer.

A semiconductor device in accordance with another aspect of the present invention includes a Si layer, a dielectric layer and a conductive member. The Si layer and the metal layer are connected to each other through a silicide layer, Ti, TiN and an oxide film provided in a contact hole defined in the dielectric layer.

The invention also provides a method for manufacturing a semiconductor device that includes a Si layer, a dielectric layer and a conductive member. The method includes: forming a contact hole in the dielectric layer to expose the Si layer; coating Ti by sputtering; after the step of sputtering the Ti, forming Ti nitride by nitriding a surface of the Ti in an nitrogen atmosphere without lowering the degree of vacuum; exposing for a predetermined period the surface of the Ti nitride to an atmosphere that speeds up formation of an oxide layer thereon; and forming the conductive member, to thereby connect the Si layer and the conductive member.

Also, the method may further include: after the step of exposing for a predetermined period the surface of the Ti nitride to an atmosphere that speeds up forming an oxide layer thereon, forming a silicide layer at an interface between the Si layer and the Ti.

The invention also provides a method for manufacturing a semiconductor device that includes a Si layer, a dielectric layer and a conductive member. The method includes: forming a contact hole in the dielectric layer to expose the Si layer; coating Ti by sputtering; after the step of sputtering the Ti, forming Ti nitride by nitriding a surface of the Ti in an nitrogen atmosphere without lowering the degree of vacuum, and annealing in succession to form a silicide layer at an interface between the Si layer and the Ti; conducting an oxygen plasma process to form an oxide layer on a surface of the Ti nitride; and forming the conductive member.

### BRIEF DESCRIPTION OF THE DRAWINGS

FIG. 1 is a cross-sectional view of a wiring structure of a contact section in a conventional semiconductor device;

FIG. 2 is a cross-sectional view of a modified example of the structure shown in FIG. 1;

FIG. 3 is a cross-sectional view that shows a first cross section of a major section in a step of a method for manufacturing a semiconductor device with the structure shown in FIG. 1;

FIG. 4 is a cross-sectional view that shows a second cross section of a major section in a step after the step shown in FIG. 3 of the method for manufacturing a semiconductor device with the structure shown in FIG. 1;

FIG. 5 is a cross-sectional view that shows a third cross section of a major section in a step after the step shown in FIG. 4 of the method for manufacturing a semiconductor device with the structure shown in FIG. 1;

FIG. 6 is a cross-sectional view that shows a first cross section of a major section in a step of another method for manufacturing a semiconductor device with the structure shown in FIG. 1;

FIG. 7 is a cross-sectional view that shows a second cross section of a major section in a step after the step shown in FIG. 6 of the other method for manufacturing a semiconductor device with the structure shown in FIG. 1;

FIG. 8 is a cross-sectional view that shows a third cross section of a major section in a step after the step shown in FIG. 7 of the other method for manufacturing a semiconductor device with the structure shown in FIG. 1;

FIG. 9 is a cross-sectional view that shows a fourth cross section of a major section in a step after the step shown in FIG. 8 of the other method for manufacturing a semiconductor device with the structure shown in FIG. 1;

FIG. 10 is a cross-sectional view that shows a cross section of a wiring structure of a contact section in a conventional semiconductor device.

### DETAILED DESCRIPTION OF PREFERRED EMBODIMENTS

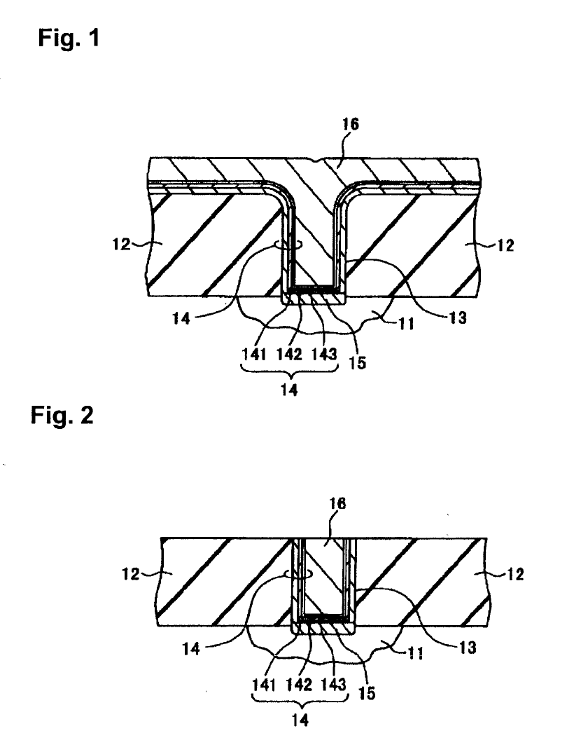

FIG. 1 is a cross-sectional view of a structure of a main part of a semiconductor device in accordance with one embodiment of the present invention. A diffusion layer 11 relating to a circuit element is formed on a Si layer, for example, on a Si semiconductor substrate. A wiring structure is electrically connected to Si of the diffusion layer 11 through a contact hole 13 defined in an interlayer dielectric layer 12 that is formed on a SiO₂ film. The wiring structure is formed as follows.

A conduction member 16 containing aluminum as its main composition, and including, for example, at least a small amount of Cu (about 0.5%), is provided. A barrier layer 14 is provided between the conduction member 16 and the diffusion layer 11. The barrier layer 14 includes a Ti layer 141 as a barrier metal. The Ti layer 141 forms a suicide connection section 15 on the side that it contacts the diffusion layer 11.

Furthermore, the barrier layer 14 includes nitride and oxide layers of the Ti layer 141, and more specifically, extremely thin TiN layer 142 and TiOₓ layer 143, on the side that it contacts the conduction member 16. The TiOₓ layer 143 is an amorphous layer that is thinner than the TiN layer.

FIG. 2 is a cross-sectional view of a modified example of the structure shown in FIG. 1, where the same elements as those shown in FIG. 1 are indicated by the same reference numbers. More specifically, a wiring plug that forms a via is provided as a wiring structure.

Each of the structures of the embodiments described above has a silicide connection section 15 to realize a low resistance contact. Also, the TiN layer 142 and TiOₓ layer 143 that are present as the barrier layer 14 on the side of the conduction member 16, in particular the TiOₓ layer 143 having an extremely thin structure has a good barrier property.

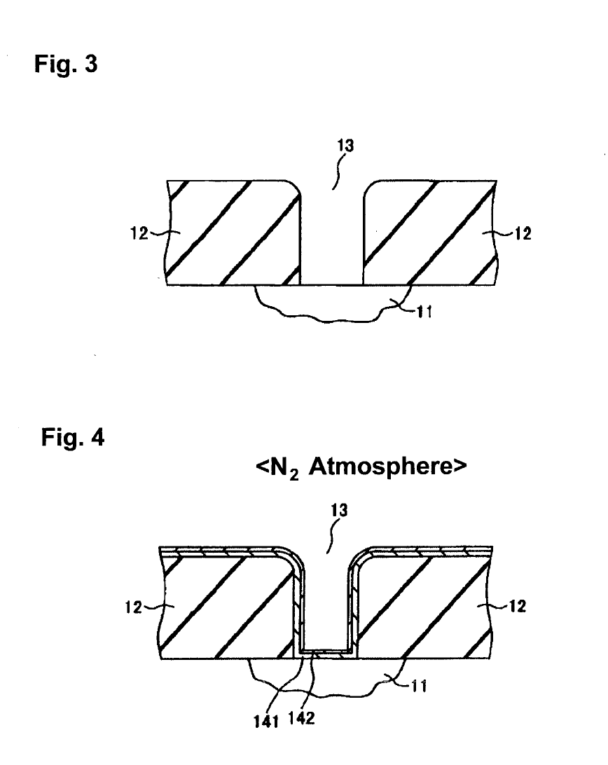

FIGS. 3-5 are cross-sectional views that show in cross-section steps of a first method for manufacturing a semiconductor device with the structure shown in FIG. 1.

As shown in FIG. 3, a diffusion layer 11 relating to a circuit element is formed in a Si semiconductor substrate, and an interlayer dielectric layer 12 that is formed of a SiO₂ film is formed thereon. A photolithography technique is used to form a resist pattern, and an etching is conducted to form a contact hole 13 in the interlayer dielectric layer 12 that reaches the diffusion layer 11. The resist is removed after the contact hole 13 is formed. The diameter of the contact hole 13 may be, for example, 0.65-0.7 μm. An inverse sputtering that expands a frontage of the contact hole 13 may be conducted.

Next, as shown in FIG. 4, a sputtering process is conducted using a sputter apparatus (not shown). Here, a Ti layer 141 is formed with the sputter apparatus that is equipped with a Ti garget. The Ti layer 141 is formed on the entire surface, such that it covers at least the diffusion layer 11 at a bottom section of the contact hole 13, and its thickness may preferably be about 50-130 nm (more preferably about 80 nm).

Next, the surface of the Ti layer 141 is nitrided in an N₂ atmosphere at about 360-500° C. (preferably 400° C. or higher). By this step, a thin TiN layer 142 with a thickness of about 3 nm is formed on the surface of the Ti layer 141 without conducting a sputtering step. Here, an oxygen partial pressure is maintained at zero “0” in the step of forming the Ti layer 141 through the nitriding step. In other words, during these steps, the process is conducted while avoiding an oxygen atmosphere. For example, the semiconductor device is moved from a Ti sputter treatment chamber where the Ti layer 141 is formed to another treatment chamber in the same sputter apparatus while maintaining the vacuum conduction, and the nitriding step is conducted in the other chamber.

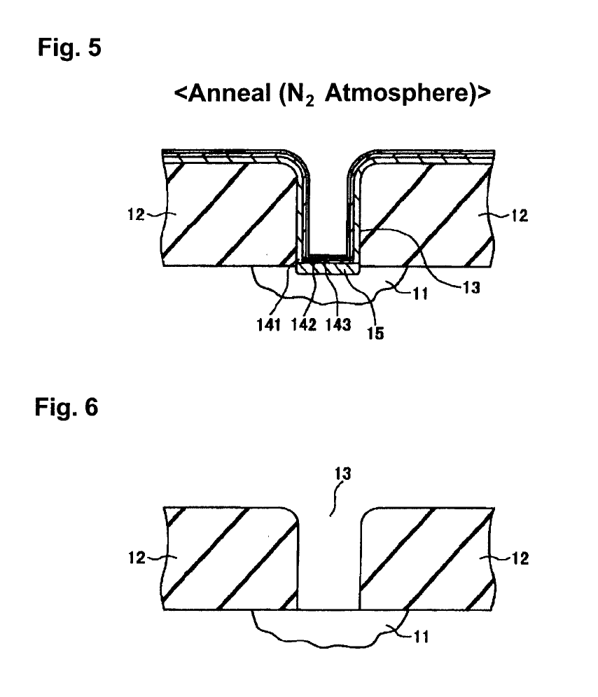

Next, as indicated in FIG. 5, it is transferred to a lamp anneal apparatus (not shown). The transfer is conducted in an atmosphere containing oxygen. If the transfer is conducted in an air atmosphere, the transfer in an atmosphere containing oxygen is readily realized. Next, an anneal step is conducted. For example, a rapid heating anneal treatment is conducted, for example, at about 700-800° C. for about 30 seconds in an N₂ atmosphere. As a result, the TiN layer 142 is further nitrided, and fired and solidified, and takes in O₂ when it is transferred to the lamp anneal apparatus, such that a thin TiOₓ layer 143 having a thickness of several Angstrom (less than 1 nm) is formed on the surface of the TiN layer 142.

Also, at the same time, through the heat treatment process described above, a silicide connection section 15 that is formed of a silicide layer of Ti (Ti₂ Si₃ layer) is formed on the side where the Ti layer 141 contacts the diffusion layer 11.

Then, a conduction member 16 is formed over the entire surface by a sputtering method or the like. Next, using a photolithography technique, a specified wiring pattern is formed while leaving area over the contact hole 13. As a result, a wiring structure shown in FIG. 1 is obtained. Alternatively, after a conduction member 16 is formed over the entire surface by a sputtering method or the like, a technique, such as an etch back or a CMP (Chemical Mechanical Polishing), may be employed to form a wiring plug shown in FIG. 2.

By the method of the present embodiment, the silicide connection section 15 that realizes a low resistance contact is formed through the step of nitriding the surface of the Ti layer 141 in an N₂ atmosphere without decreasing the vacuum, and the rapid heating anneal treatment that is conducted in an N₂ atmosphere.

Also, the TiN layer 142 is formed without being subject to a sputtering step. This contributes to a reduction of particles. Furthermore, the TiOₓ layer 143 that covers the surface of the TiN layer 142 contributes to an enhancement in the barrier property. A foundation for forming the TiOₓ layer 143 is prepared when it is exposed to an air atmosphere during the transfer to the anneal treatment step.

When forming the TiOₓ layer 143, the surface of the TiN layer may be exposed to an air atmosphere in any manner. For example, it may be exposed during the transfer, and an oxidation treatment step may be additionally provided. Alternatively, if the sputter process and the anneal treatment are to be conducted in the same chamber, a period to introduce an air atmosphere or O₂ may be provided during the period in which N₂ gas is charged.

FIGS. 6-9 are cross-sectional views that show in cross section steps of a second method for manufacturing a semiconductor device with the structure shown in FIG. 1.

As shown in FIG. 6, a diffusion layer 11 relating to a circuit element is formed in a Si semiconductor substrate, and an interlayer dielectric layer 12 that is formed of a SiO₂ film is formed thereon. A photolithography technique is used to form a resist pattern, and an etching is conducted to form a contact hole 13 in the interlayer dielectric layer 12 that reaches the diffusion layer 11. The resist is removed after the contact hole 13 is formed. The diameter of the contact hole 13 may be, for example, 0.65-0.7 μm.

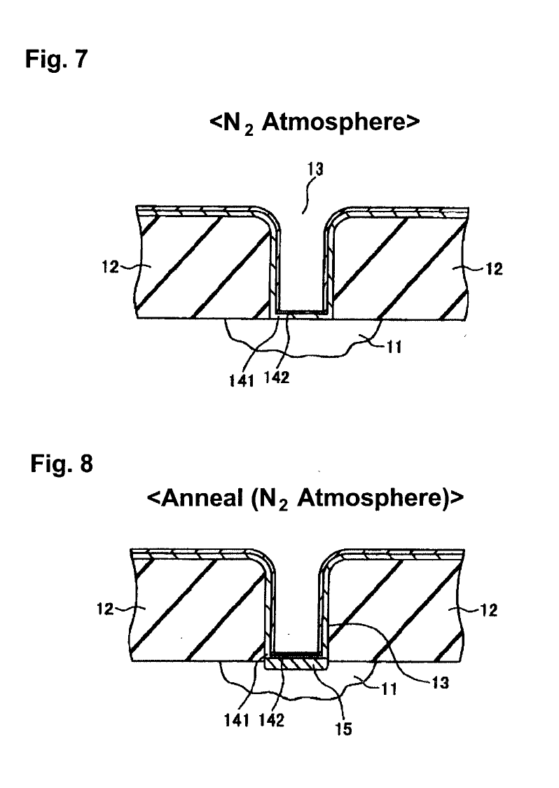

Next, as shown in FIG. 7, a sputter process is conducted using a sputter apparatus (not shown). Here, a Ti layer 141 is formed with the sputter apparatus that is equipped with a Ti garget. The Ti layer 141 is formed on the entire surface, such that it covers at least the diffusion layer 11 at a bottom section of the contact hole 13, and its thickness may preferably be about 50-130 nm (more preferably about 80 nm).

Next, the surface of the Ti layer 141 is nitrided in an N₂ atmosphere at about 360-500° C. (preferably 400° C. or higher). By this step, a thin TiN layer 142 with a thickness of about 3 nm is formed on the surface of the Ti layer 141 without conducting a sputtering step. Here, an oxygen partial pressure is maintained at zero “0” in the step of forming the Ti layer 141 through the nitriding step. In other words, during these steps, the process is conducted while avoiding an oxygen atmosphere. For example, the semiconductor device may be moved from a Ti sputter treatment chamber where the Ti layer 141 is formed to another treatment chamber in the same sputter apparatus while maintaining the vacuum conduction, and the nitriding step is conducted in the other chamber.

Next, as indicated in FIG. 8, a lamp anneal treatment is conducted. The lamp anneal treatment may be a rapid heating anneal treatment that is conducted, for example, at about 700-800° C. for about 30 seconds in an N₂ atmosphere. If the sputter apparatus in the previous stage is equipped with a lamp heating system, the lamp anneal treatment can be conducted in the same apparatus. Or, the device may be transferred to a lamp anneal apparatus. As a result, the TiN layer 142 is further nitrided, and fired and solidified.

Also, at the same time, through the heat treatment process described above, a silicide connection section 15 that is formed of a silicide layer of Ti (Ti₂ Si₃ layer) is formed on the side where the Ti layer 141 contacts the diffusion layer 11.

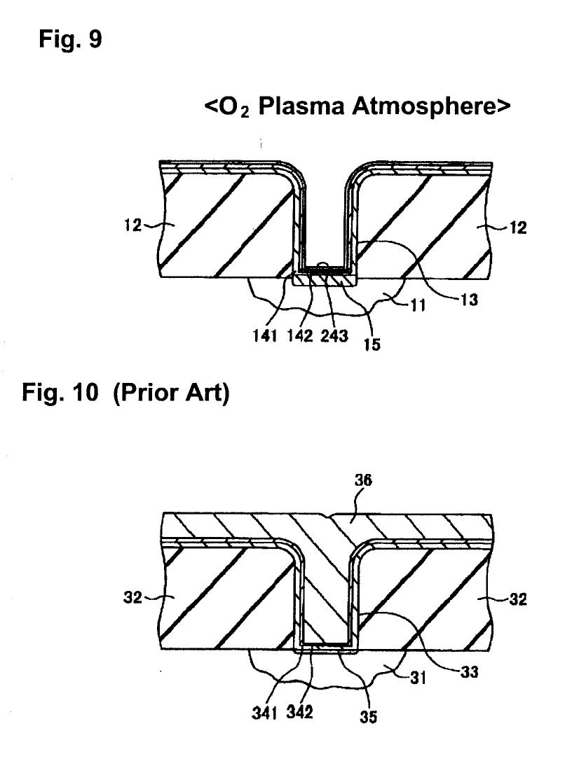

Next, as indicated in FIG. 9, an O₂ plasma treatment is conducted. In this treatment, the TiN layer 142 is exposed to an excessive oxygen radical atmosphere to form a TiO₂ layer 243 on the surface thereof. An interface between the TiN layer 142 and the TiO₂ layer 243 also includes a TiOₓ layer. As a result, the thin TiO₂ layer (including a TiOₓ layer) 243 having a thickness of several Angstrom (less than 1 nm) is formed on the TiN layer 142.

Then, a conduction member 16 is formed over the entire surface by a sputtering method or the like. Next, using a photolithography technique, a specified wiring pattern is formed while leaving area over the contact hole 13. As a result, a wiring structure shown in FIG. 1 is obtained. Alternatively, after a conduction member 16 is formed over the entire surface by a sputtering method or the like, a technique, such as an etch back or a CMP (Chemical Mechanical Polishing), may be employed to form a wiring plug shown in FIG. 2. This provides a structure in which the TiOₓ layer 143 in FIG. 2 is replaced with the TiO₂ layer (including a TiOₓ layer) 243.

Also, by the method of the present embodiment, the silicide connection section 15 that realizes a low resistance contact is formed through the step of nitriding the surface of the Ti layer 141 in an N₂ atmosphere without decreasing the vacuum, and the rapid heating anneal treatment that is conducted in an N₂ atmosphere.

Also, the TiN layer 142 is formed without conducting a sputtering step. This contributes to a reduction of particles. Furthermore, the TiO₂ layer (including the TiOₓ layer) 243, that is formed by an O₂ plasma treatment on the surface of TiN layer 142, contributes to an enhancement in the barrier property. The present invention is not limited to the embodiments described above. Also, the conduction member 16 is a member that is not suitable to directly connect to Si, and aluminum is used as a typical example. However, other materials can also be used.

As described above, in accordance with the present invention, a silicide connection section that realizes a low resistance contact with a Si diffusion layer is formed through the step of nitriding one surface of a barrier metal formed by sputtering in an N₂ atmosphere without decreasing the vacuum, and a rapid heating anneal treatment conducted in an N₂ atmosphere. A nitride layer of the barrier metal is formed without conducting a sputtering step. This contributes to a reduction of particles. Furthermore, an extremely thin oxide layer covering the surface of the barrier metal nitride layer, contributes to an enhancement of the barrier property. As a result, the present invention provides a semiconductor device having a wiring structure that reduces the particle problem, and achieves a low contact resistance and high barrier property, and a method for manufacturing such a semiconductor device.

What is claimed is:

1. A semiconductor device, comprising:
a Si layer;
a dielectric layer that defines a contact hole;
a conductive member; and
a Ti, TiN and an oxide film provided in the contact hole defined in the dielectric layer, the Si layer and the conductive member being in electrical communication with each other through the Ti, TiN and the oxide film.

2. A semiconductor device, comprising:
a Si layer;
a dielectric layer that defines a contact hole;
a conductive member; and
a silicide layer, Ti, TiN and an oxide film provided in the contact hole defined in the dielectric layer, the Si layer and the conductive member being in electrical communication with each other through the silicide layer, Ti, TiN and the oxide film.

3. A method for manufacturing a semiconductor device that includes a Si layer, a dielectric layer and a conductive member, the method comprising:
forming a contact hole in the dielectric layer to expose the Si layer;
coating Ti by sputtering;
after the step of sputtering the Ti, forming Ti nitride by nitriding a surface of the Ti in an nitrogen atmosphere without lowering the degree of vacuum;
exposing for a predetermined period the surface of the Ti nitride to an atmosphere that speeds up formation of an oxide layer thereon; and
forming the conductive member, to thereby electrically communicate the Si layer and the conductive member.

4. The method for manufacturing a semiconductor device according to claim 3, further comprising, after the step of exposing for a predetermined period the surface of the Ti nitride to an atmosphere that speeds up forming an oxide layer thereon, the step of forming a silicide layer at an interface between the Si layer and the Ti.

5. A method for manufacturing a semiconductor device that includes a Si layer, a dielectric layer and a conductive member, the method comprising:
forming a contact hole in the dielectric layer to expose the Si layer;
coating Ti by sputtering;
after the step of sputtering the Ti, forming Ti nitride by nitriding a surface of the Ti in an nitrogen atmosphere without lowering the degree of vacuum, and annealing in succession to form a suicide layer at an interface between the Si layer and the Ti;
conducting an oxygen plasma process to form an oxide layer on a surface of the Ti nitride; and
forming the conductive member.
